(19) United States
(12) Patent Application Publication
(10) Pub. No.: US 2005/0167730 A1
(43) Pub. Date: Aug. 4, 2005

(54) Cell structure of nonvolatile memory device

(76) Inventors: Chien-Hsing Lee, Jhubei City (TW); Chin-Hsi Lin, Hsinchu (TW); Jhyy-Cheng Liou, Jhubei City (TW)

Correspondence Address: J C PATENTS, INC., 4 VENTURE, SUITE 250, IRVINE, CA, 92618, US

(21) Appl. No.: 10/848,592

(22) Filed: May 17, 2004

Related U.S. Application Data
(60) Provisional application No. 60/541,609, filed on Feb. 3, 2004.

(51) Int. Cl. H01L 29/76

(52) U.S. Cl. 257/314

(57) ABSTRACT

The invention is directed to a nonvolatile memory device. Each memory cell is formed to have the depletion mode operation by doped opposite conductive-type dopants to the substrate at the surface region under the gate electrode, so that the depletion memory cell is formed. The charge-storing structure layer is, for example, an O/N/O structure layer, wherein the nitride layer is used to store the charge. The erasing operation speed can be improved.

### CROSS-REFERENCE TO RELATED APPLICATION

This application claims the priority benefits of U.S. provisional application titled “SONOS HAND FLASH” filed on Feb. 3, 2004. All disclosure of this application is incorporated herein by reference.

### BACKGROUND OF THE INVENTION

1. Field of Invention

The present invention relates to semiconductor memory device. More particularly, the present invention relates to a nonvolatile memory device with oxide/nitride/oxide (O/N/O) structure, wherein the nitride can be replaced by other charge storage layer.

2. Description of Related Art

Nonvolatile memory device, such as flash memory device, allows multiple times erase and program operation inside system. As a result, the nonvolatile memory is suitable for use in many of advance hand-held digital apparatuses, including solid state disks, cellar phones, digital cameras, digital movie cameras, digital voice recorders, or PDA, that are demanding a low-cost, high-density, low-power-consumption, highly reliable file memory.

Basically, data nonvolatile memory has two types of cell structures. One is a design of Stack Gate NAND memory device, having the double polysilicon NAND type memory cell with polysilicon 1 as the floating gate to store charge. The other one is SONOS memory device, having single polysilicon gate with O/N/O charge storage structure layer, wherein the nitride serves as storage node. Here, SONOS is known as an O/N/O charge storage structure layer located between the silicon gate and silicon substrate. The stack gate NAND nonvolatile memory cell has larger size than the SONOS cell. The SONOS memory device is operated by adopting channel hot carriers for programming and band-to-band (B-B) hot holes for erasing. Cell size of SONOS cell is around 4F², here F represents a size unit used in semiconductor fabrication. However, the reliability of SONOS cell is very sensitivity to hot electron and hot hole stress during program and erase operation.

FIG. 1 is a circuit diagram, schematically illustrating the cell array with SONOS design. In FIG. 1, the transistors 104 coupled with SGD line and SGS line are used to select the memory block. For each block, several word lines WL0, WL1, . . . , and WL31 and several bit lines BL0, BL1, . . . , and BLn are used to access each memory cell 100. The operation voltages for erasing, reading, and programming operations are for example listed in Table 1.

TABLE 1

| | | | Program | |
|---|---|---|---|---|
| NODE | ERASE | Program (selected) | (non-selected) | Read |
| BL | FG | GND | VCC | 1 V |
| SGD | FG | VCC | VCC | VCC |
| WL0 | GND | ½ VPP | ½ VPP | VCC |
| WL1 | GND | ½ VPP | ½ VPP | VCC |
| WL2 | GND | ½ VPP | ½ VPP | VCC |
| WL3 | GND | ½ VPP | ½ VPP | VCC |
| WL4 | GND | ½ VPP | ½ VPP | VCC |
| WL5 | GND | VPP | VPP | GND |
| (selected WL) | | | | |
| WL6 | GND | ½ VPP | ½ VPP | VCC |
| WL7 | GND | ½ VPP | ½ VPP | VCC |
| SGS | FG | GND | GND | VCC |
| VS | FG | GND | GND | GND |
| P-WELL | VPP | GND | GND | GND |

In Table 1, only 8 word lines are shown as the example. VPP represent a positive voltage level for programming. VCC represents a positive voltage level to turn on the cell for passing the source/drain regions to the selected cell. FG represents the floating state. GND represents the ground voltage. The operation should be known by the skilled artisans and is not further described.

In semiconductor structure, the circuit in FIG. 1 can be fabricated by semiconductor technology, as shown in FIG. 2A and FIG. 2B for two cross-sectional views. In FIG. 2A, a semiconductor substrate, such as P-type substrate (P-SUB) is used. Due to fabrication in logic area of the memory device, different types of doped wells, such as DN-well and TP-well are usually formed in the substrate P-SUB. Then, the N-type memory cells are formed in the P-type well. In general, the memory cell string with respect to one bit line us shown in FIG. 2A. Two MOS transistors 200 in one bit are, for example used, for selection. One transistor 200 has the gate electrode coupled to the SGD voltage line, and one source/drain (S/D) region is coupled to the bit line BL. The other transistor 200 has the gate electrode coupled to the SGS voltage line, and one source/drain region is coupled to the source voltage VS. One memory cell 208 includes the gate electrode 202, which is coupled to the word line WL. The O/N/O structure layer 204 is between the gate electrode 202 and the substrate in P-type well region (TP-well). The two S/D regions 206 are formed in the substrate at each side of the gate electrode 202. Usually, for the a threshold voltage (VT) adjusting doped region 210 is formed at the surface of the substrate under the gate electrode 202. Conventionally, the enhancement mode in semiconductor property is designed for the SONOS cell. In this situation, for the p-type well, the VT adjusting doped region 210 is further doped with P-type dopant to have P+ doped region.

For the other cross-section view along the word line WL, which is usually called polyl, is shown in FIG. 2B. The word line WL by itself also serves as the gate electrode 202. The isolation structure, such as the shallow trench isolation (STI), are used to isolate the adjacent memory cells. The structure and fabrication process to form the device in FIG. 2 should be known by the skilled artisans and are not further described. However, it should be noted that the enhancement mode is used for the conventional SONOS cell design. It would cause some problems, which are to be discussed.

Usually, the threshold value is used to store the binary data. Typically, a negative threshold value represents a “1” binary data and the positive threshold value represent a “0” binary data. FIG. 3 shows the basic mechanism for erasing, programming, and reading operations. For the erasing operation, the holes are to be driven into the middle nitride layer of the O/N/O layer 204 from the substrate by applying one set of proper voltages to create the desired electric filed. For the programming operation, the electrons are to be injected into the middle nitride layer of the O/N/O layer 204 from the substrate by applying another set of proper voltages to create the desired electric filed. For the reading operation, a set of reading voltages are applied to read the accessed cell to detect the threshold value, so as to determine the binary data, based on the design. However, the conventional enhancement mode design causes the erasing speed to be slow. The reasons are shown in FIGS. 4A-4F.

FIGS. 4A-4F are energy band diagram with respect to the O/N/O structure layer. In FIGS. 4A-4C, the erasing operation for the enhancement mode cell is shown. In FIG. 4A, the O/N/O structure layer is indicated with the energy slopes 400, 402, and 404. For the enhancement mode design, the erasing operation is to drive the holes into the nitride layer being trapped. In this situation, the holes are driven in the direction as indicated by the thick arrow at the bottom. In FIG. 4B, the middle stage of erasing operation is shown. The holes 406 following the arrow 408a are tapped into the nitride layer N. At this stage, due to the trapped holes 406, the electric field becomes weaker, wherein the slop of energy is reduced. Also and, the electrons at the polysilicon gate has the tendency to be tunneling over the top oxide layer into the nitride layer, as indicated by arrow 408b. This also reduces the speed to trap sufficient holes in the nitride layer N. In FIGS. 4D-4F, the programming operation is shown. The operation is to drive electrons into the nitride layer to neutralize the positive holes. In FIG. 4F, when the programming operation is complete, the nitride layer is substantially neutralized.

Clearly, the conventional enhancement mode design for the SONOS memory device has at least the disadvantage of slow erasing speed. So far, this issue of slow erasing speed is not discussed or even not discovered by the prior art. The invention has investigate the issue and has proposed a solution.

### SUMMARY OF THE INVENTION

The invention provides a structure of nonvolatile memory device, of which at least the erasing speed in operation can be significantly improved.

The invention provides a structure of nonvolatile memory device. Each memory cell is formed to have the depletion mode operation by doped opposite conductive-type dopants to the substrate at the surface region under the gate electrode, so that the depletion memory cell is formed. The charge-storing structure layer is, for example, an O/N/O structure layer, wherein the nitride layer is used to store the charge. The erasing operation speed can be improved.

The invention provides a cell structure of a nonvolatile memory device. A substrate is provided, having at least a doped well being doped with first-type dopants. A charge-storing structure layer is disposed on the substrate within the doped well. A gate electrode is disposed on the charge storing layer. Source/drain (S/D) regions are formed in the substrate at each side of the gate electrode. In addition, a threshold voltage adjusting region is formed at a surface region of the substrate under the charge-storing structure layer to have a depletion transistor mode. In this manner, the threshold voltage adjusting region is doped with second-type dopants, opposite to the first-type dopants.

In another aspect of the invention, the first-type dopants are P-type dopants and the second-type dopants are N-type dopants.

In another aspect of the invention, the gate electrode is a part of a word line.

In another aspect of the invention, the charge-storing structure layer comprises a bottom oxide layer on the substrate, a charge trapping layer on the bottom oxide layer, and a top oxide layer on the charge trapping layer.

The invention also provides a cell string structure with respect to a bit line. The cell string structure comprises a substrate having a plurality of doped wells, including a memory well doped with first-type dopants. A plurality of charge-storing structure layers are formed on the substrate within the memory well. A plurality of memory gate layers are respectively formed on the charge-storing structure layers. A plurality of threshold voltage adjusting region are formed at a surface region of the substrate under the charge-storing structure layers to have a depletion operation mode. The threshold voltage adjusting region is doped with second-type dopants, opposite to the first-type dopants of the memory well. A plurality of doped regions are formed in the substrate within the memory well at each side of the memory gate layers, so that a plurality of memory cells are formed and coupled in series.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a circuit diagram, schematically illustrating the cell array with SONOS design.

FIGS. 2A-2B are cross-sectional views, schematically illustrating the semiconductor structure of a SONOS memory device.

FIG. 3 is a drawing, schematically illustrating a mechanism for the operations of erasing, programming, and reading.

FIGS. 4A-4F are energy band diagrams, schematically illustrating the mechanism for erasing and programming on the ONO layer for the conventional enhancement memory cell of enhancement mode design.

FIGS. 5A-5F are cross-sectional views, schematically illustrating the fabrication processes for depletion mode SONOS memory device, according to an embodiment of the invention.

FIGS. 6A-6F are energy band diagrams, schematically illustrating the mechanism for erasing and programming on the ONO layer for the depletion memory cell, according to the embodiment of the invention.

FIGS. 7A-7B are drawings, schematically illustrating the comparison relation of threshold voltages with respect to enhancement mode and depletion mode, according to the invention.

### DESCRIPTION OF THE PREFERRED EMBODIMENTS

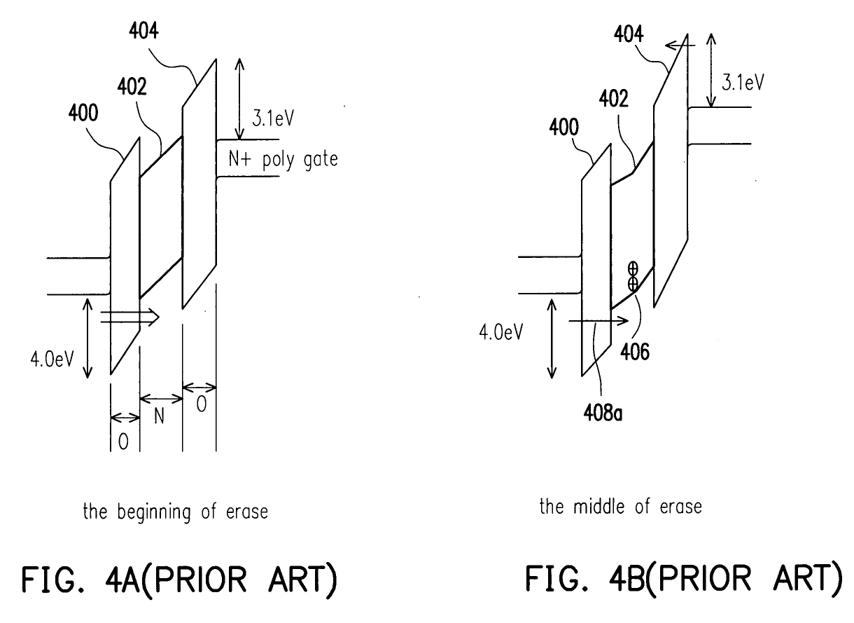

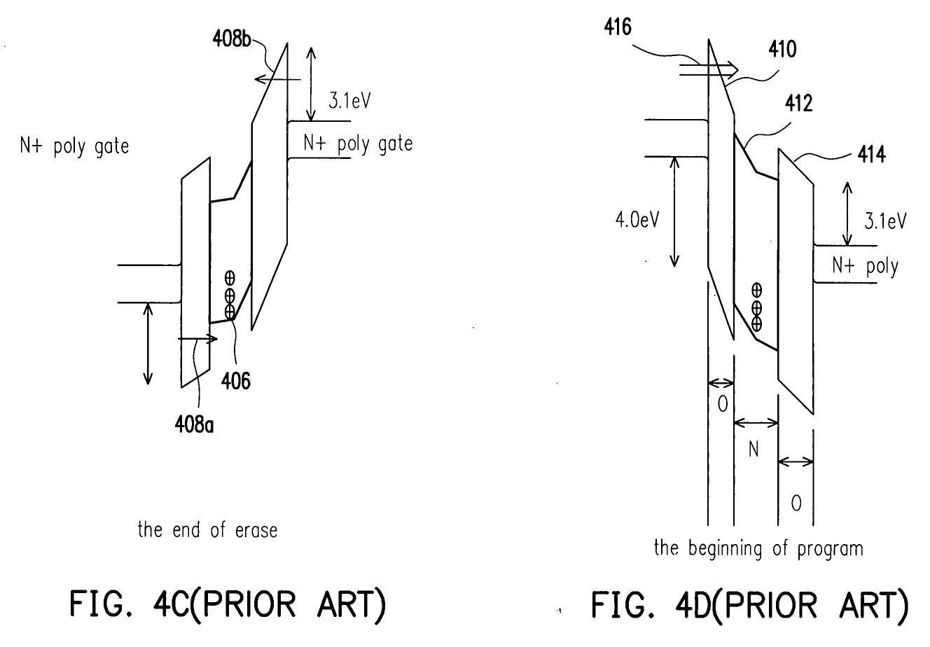

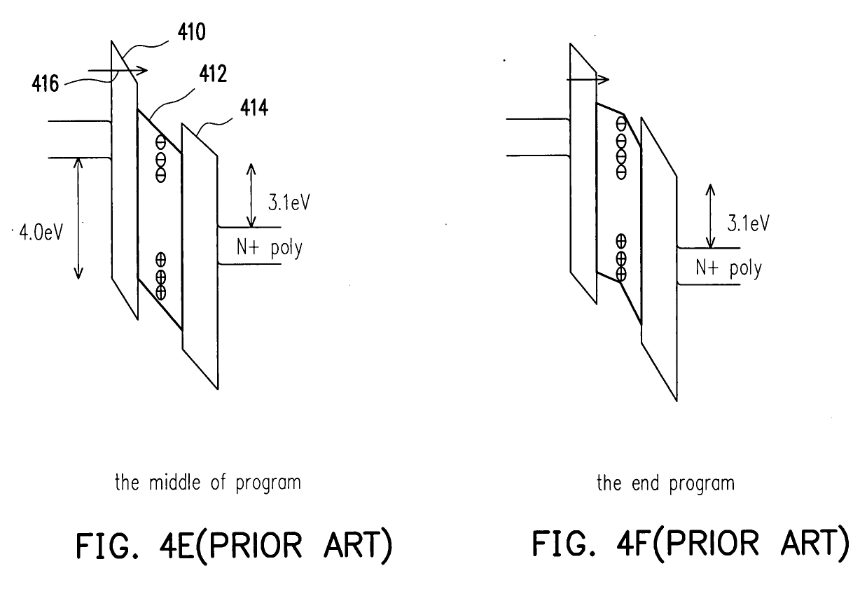

In the invention, a novel SONON memory device in depletion mode design is proposed. The present invention at least can improve the erasing speed. The invention has investigated the conventional enhancement mode SONOS memory device and discovered that at least the erasing speed as discussed in FIGS. 4A-4C is not sufficiently fast. After investigating the conventional issues in better details, the present invention proposed a depletion mode SONOS memory device. Due to the use of the properties in depletion mode, the erasing speed can be significantly improved.

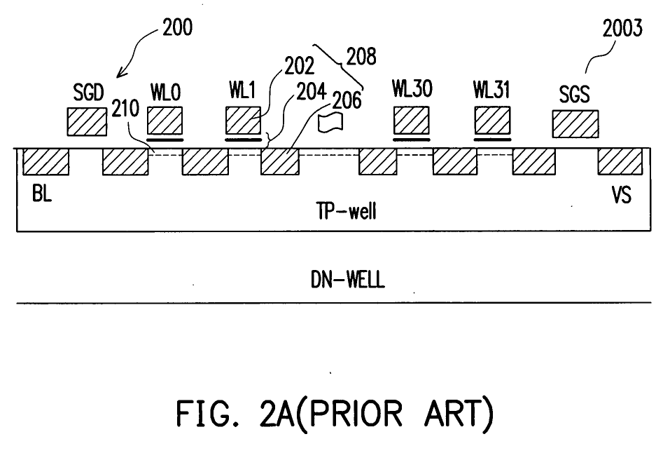

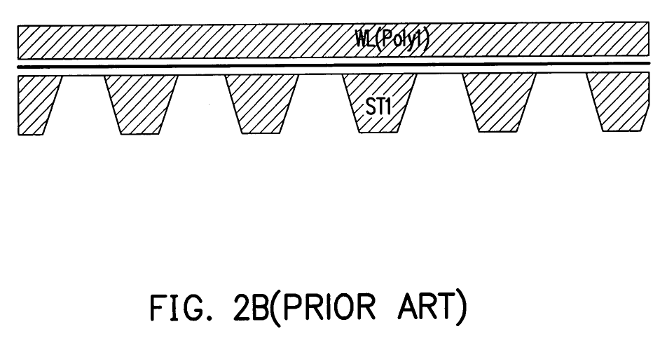

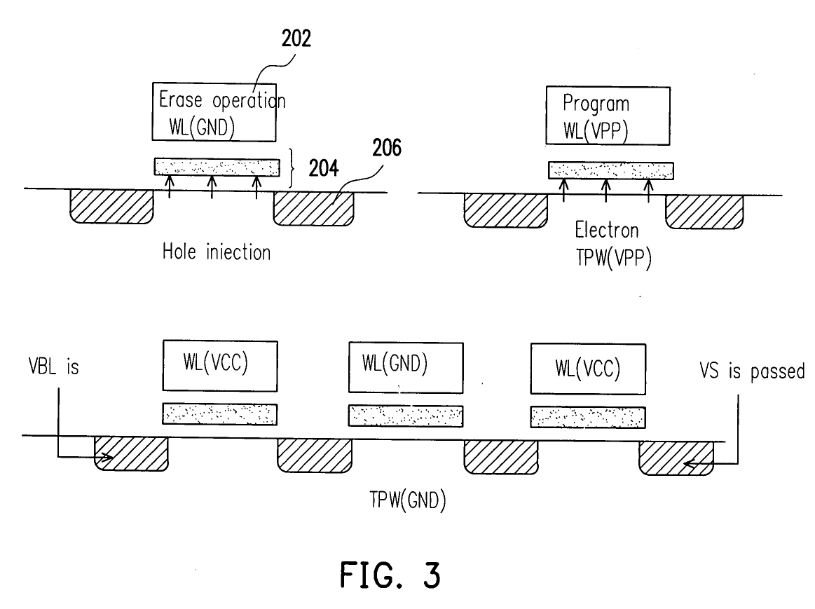

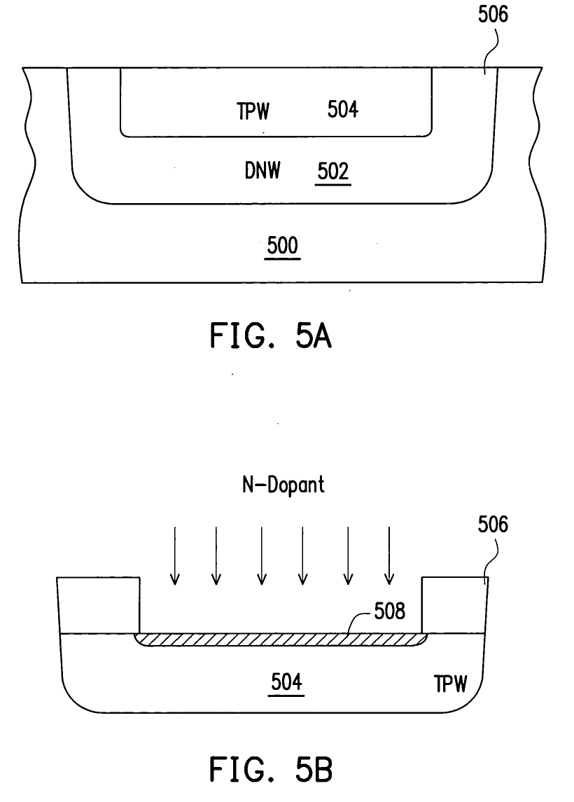

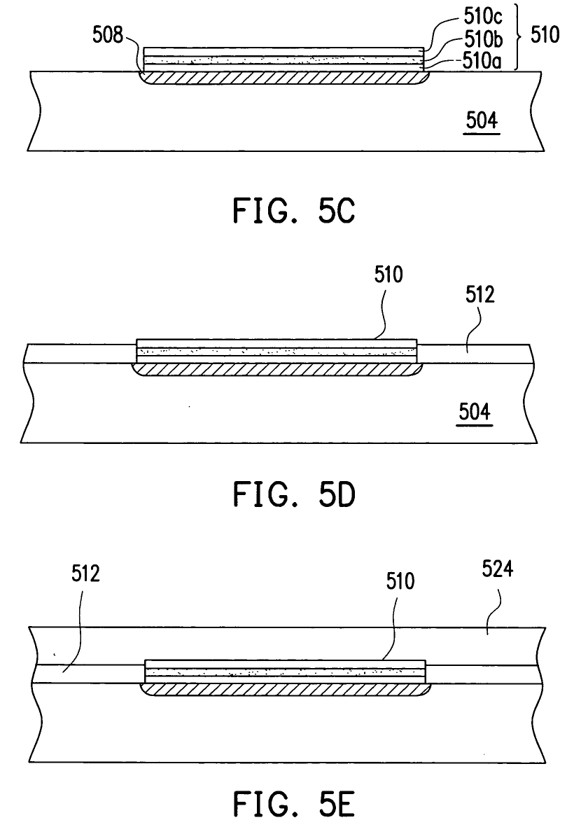

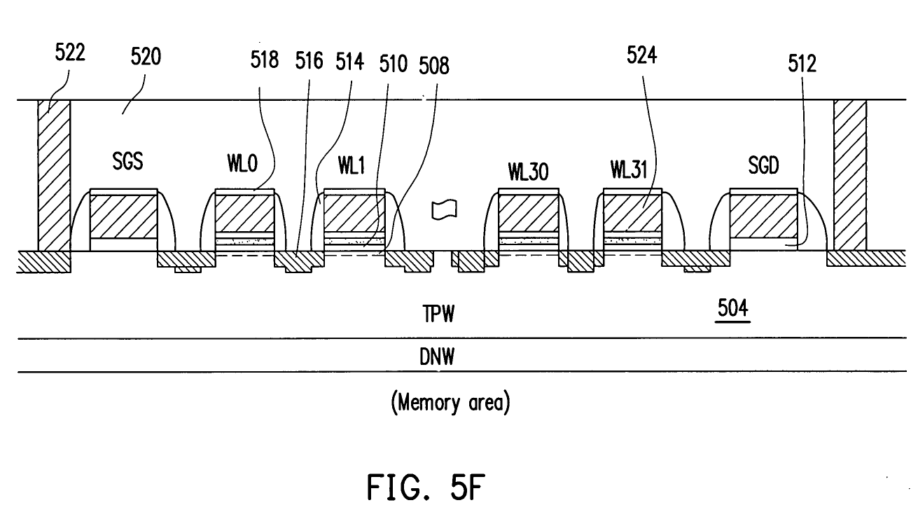

FIGS. 5A-5F are cross-sectional views, schematically illustrating an example of the fabrication process to form the nonvolatile memory, according to an embodiment of the invention. In FIG. 5A, several doped wells 502, 504 are formed in a substrate 500, such as a P-type substrate. The memory device is a complementary metal-oxide semiconductor (CMOS) device, including peripheral area formed with for example logic devices and the memory area formed with memory cells. In the memory area shown in FIG. 5A, for the example, the SONOS nonvolatile memory device are to be formed thereon. However, the N-type well 502 may also be formed in the substrate 500, and the triple P-type well (TPW) 504 is formed in the well 502 for forming NMOS memory cells. Also and, several isolation structures, such as shallow trench isolations (STI) in FIG. 2B, have been formed to separate the memory MOS cells and the MOS transistors. The actual process may needs several semiconductor fabrication processes, such as photolithographic process, etching process, deposition process, and implantation process. These processes should be known by the skilled artisans and not described in detail.

In FIG. 5B, in order to form a depletion NMOS memory cell, a photoresist layer 506 is formed on the substrate 500 to expose a portion of the well 504. An implantation process is performed to form a doped region 508 at the surface of the substrate within the well 504. The implanted dopants are different from the conductive type of the well 504. In this example, the well 504 is P-type then the dopants are N-type such as P or As. The doped region 508 is used to form the memory cell in depletion mode. In other words, the doped region 508 is also called the threshold voltage (VT) adjusting region. However, this VT adjusting doped region 508 is not limited to be formed at this step and then may also be formed later.

In FIG. 5C, after the photoresist layer 506 is removed, an O/N/O structure layer 510 can be formed on the substrate within the well 504. The O/N/O structure layer 510 includes, for example, a bottom oxide 510a, a nitride layer 510b, and a top oxide layer 510c, in which the nitride layer 510b is used to store or trap the charges. However, the nitride layer 510b can be replaced by other material with the like function, such as tantalum oxide, aluminum oxide, or nano-crystal silicon.

In FIG. 5D, a gate dielectric layer 512 is formed on the substrate at the region not covered by the O/N/O structure layer 510. The gate dielectric layer 512 usually is the gate oxide layer by, for example, deposition process or thermal process. The gate oxide layer 512 is used for form the MOS selection transistor later while the O/N/O structure layer 510 is used for the SONOS memory cells later.

In FIG. 5E, a polysilicon layer 524 is formed over the O/N/O structure layer 510 and the gate dielectric layer 512 by for example a chemical vapor deposition (CVD) process. In FIG. 5F, the polysilicon layer 524, the O/N/O structure layer 510, and the gate dielectric layer 512 are patterned by photolithographic and etching processes. The polysilicon layer 524 is then patterned into several polysilicon gate layers 524. Some of the polysilicon strip layers 524 over the O/N/O structure layer 510 serve as the gate electrodes and the word lines. The polysilicon strip layers 524 over the gate dielectric layer 512 serve as the gate electrode and the power feeding line.

in order to form the MOS transistor, an implantation process is performed to form, for example, a lightly doped region in the substrate within the well 504 between the gate electrodes 524. Spacers 514 are formed on the sidewall of the gate electrode 524 and the O/N/O structure layer 510 or the gate dielectric later 512. Another heavy implantation process is performed to implant dopants in to the substrate to form the heavily doped region, by using the gate electrode 524 and the spacer 514 as the mask. The light doped region, such as the lightly doped drain (LDD) region, and the heavily doped region together serve as the S/D region.

The transistors indicated by SGD and SGS are the usual MOS transistors to serve the selection transistor, wherein the gate electrode 524 are respectively coupled to the selection voltage SGD and SGS. One S/D region of each selection transistor (SGD or SGS) is coupled to the S/D region for the beginning or the last memory MOS cell. Preferably, the one of the S/D is commonly used. However, the other S/D region of each selection transistor (SGD or SGS) is to be coupled to a bit line or a source voltage.

A planarized dielectric layer 520 is formed over the transistors and the memory cells. The patterning process is performed to form the via holes to expose the S/D regions of the selection transistors. The conductive material is filled into the via hole to form the interconnecting plug 522, which allows the S/D regions of the selection transistor (SGD, SGS) to be coupled to the bit line or the source voltage. For the subsequent process, the interconnecting structure (not shown) is formed.

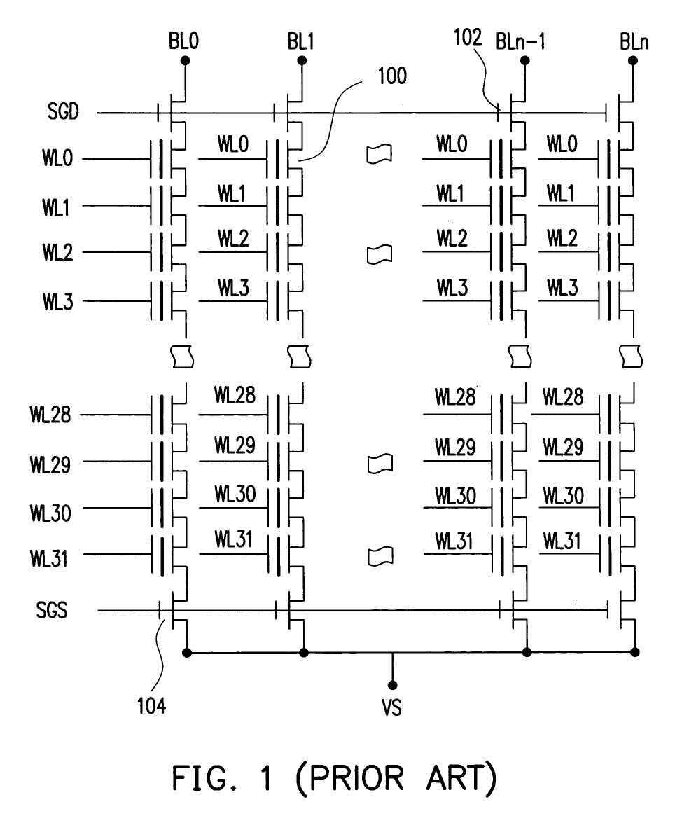

In the foregoing descriptions of the fabrication process, some detail descriptions are omitted but should be known by the skilled artisans, according to the desired structure. In other words, the fabrication processes to form the foregoing desired structure are not necessary to be limited to the foregoing processes. The structure can be equivalent to the circuit in FIG. 1. However, the memory cells are now operated in depletion mode due the threshold voltage adjusting region 508 in the substrate under the gate electrodes 524. The fabrication processes to accomplish the final memory device are also omitted but should be known by the skilled artisans.

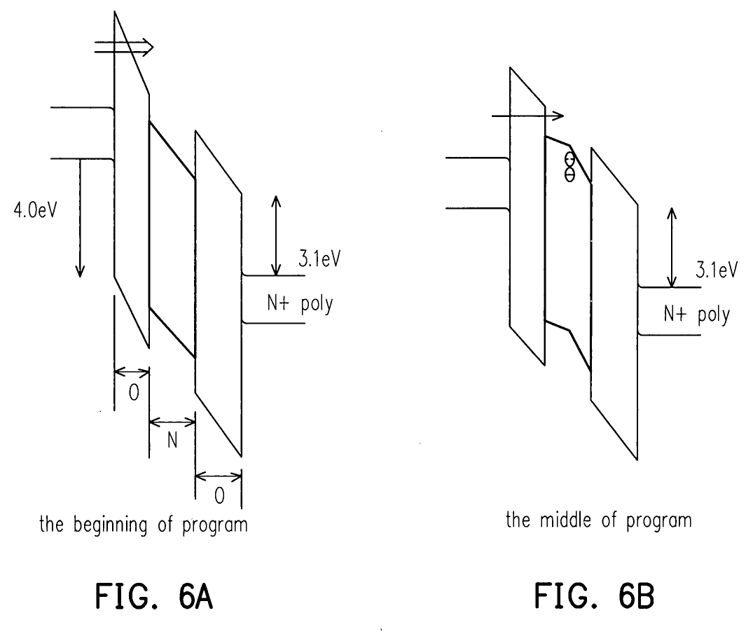

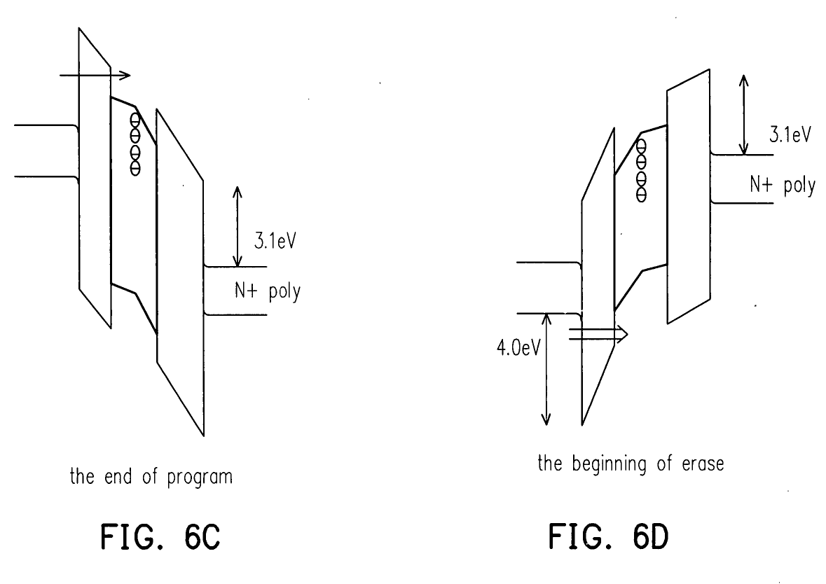

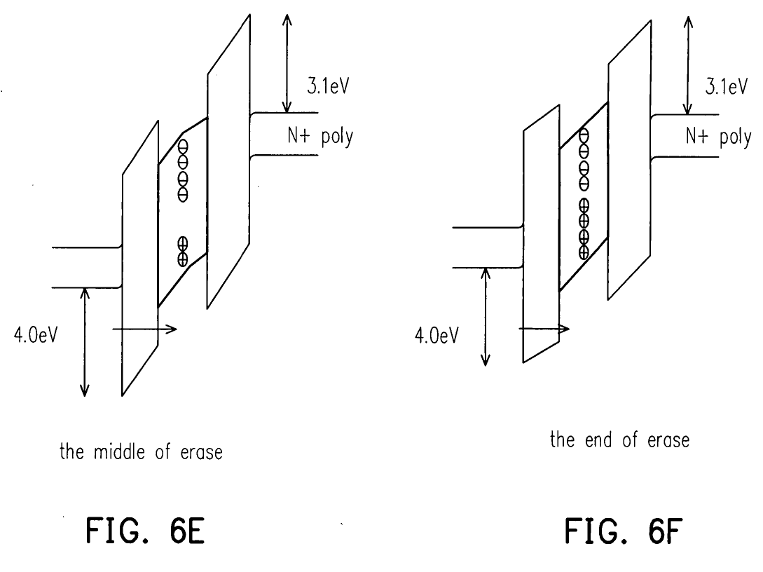

One of the essential features of the invention is to form the memory cell is depletion mode. The properties of the depletion mode allows the erasing process to be faster. FIGS. 6A-6F are energy band diagrams, schematically illustrating the mechanism for erasing and programming on the ONO layer for the depletion memory cell, according to the embodiment of the invention.

In the invention, since the memory cells are in depletion mode design, the memory cells are not necessary to be pre-erasing. The programming process can be performed. In FIGS. 6A-6C, the programming processes are shown. In programming process, the negative charges, or hot electrons, are to be trapped in the nitride layer of the O/N/O structure layer while the erasing process is to inject holes into the nitride layer for neutralizing the nitride layer with the trapped electrons. In FIG. 6A, as indicated by arrow, electrons are driven into the nitride layer by tunneling over the bottom oxide. In FIG. 6B, the electrons are accumulated in nitride layer. In FIG. 6C, the electrons with sufficient amount are trapped into the nitride layer.

In FIGS. 6D-6E, the erasing process is shown. The erasing process is to neutralize the nitride layer, in which the electrons trapped in the nitride layer are to be annihilated. In FIG. 6D, the nitride layer has trapped electrons, which are to be annihilated by the holes. The trapped electrons are helpful to enhance the electric field for driving the holes into the nitride layer while the trapped electrons resist the electrons to be tunneled from the top oxide into the nitride layer. In FIG. 6E, the holes are easily to be trapped in the nitride layer. In FIG. 6E, the nitride layer is gradually neutralized without resistance. In FIG. 6F, the sufficient amount of holes are injected into the nitride layer for annihilate with the electrons. As a result, the nitride layer is neutralized. Two states of the nitride layer are having electrons or having no electrons. The electrons affect the threshold values, so as to represent two binary data in one memory cell.

In comparing with the conventional enhancement mode memory cell, the conventional memory is necessary to pr-erase whole cells before the usually programming and erasing are performed. However, the proposed depletion mode memory cell is not necessary to have the pre-erasing step. The pre-erasing process is saved in the invention for the depletion mode. The operation mechanism for the proposed depletion modes memory cell is also different from the conventional enhancement mode memory cell as described in FIGS. 6A-6F.

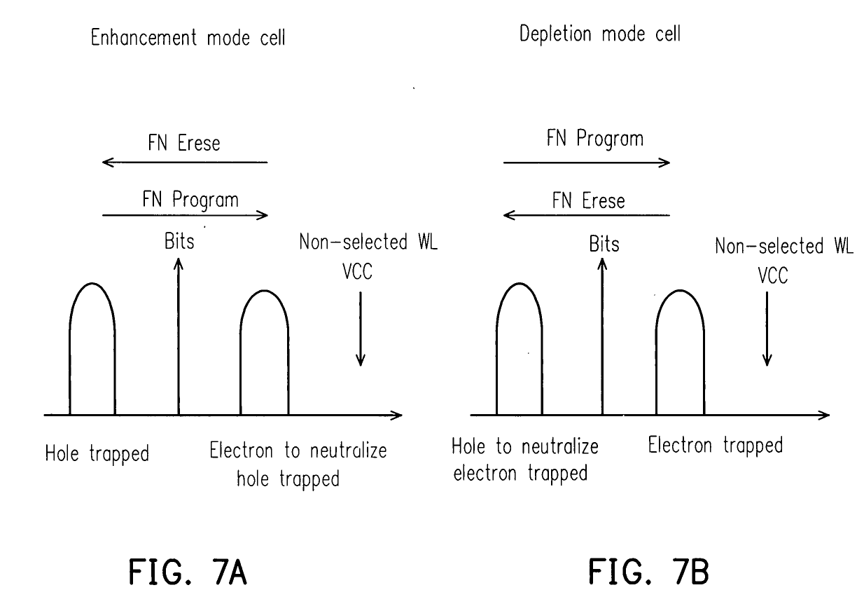

In FIGS. 7A-7B, the relation of threshold voltages with respect to enhancement mode and depletion mode are shown. In FIG. 7A, the enhancement mode memory cell is shown. The horizontal axis is the threshold value and the vertical axis is the bit number. In the memory device, some number of bits is at high threshold value and some number of the bits is at the low threshold value. The erasing process for the enhancement mode is to trap holes into the nitride layer. At the final stage, the holes are not easy to be trapped in the nitride layer with the sufficient amount. In programming process for the enhancement mode, the electrons are injected into the nitride for annihilating with the trapped holes.

However, In FIG. 7B for the depletion mode, the erasing process is to inject holes into the nitride layer for annihilating with the trapped electrons in the nitride layer. The erasing process is easier. For the programming process, the hot electrons are simply trapped in the nitride layer.

According to the depletion mode memory cell, the operation voltages can be, for example, listed in Table 2.

TABLE 2

| | | | Program (non- | |
|---|---|---|---|---|
| NODE | ERASE | Program (selected) | selected BL) | Read |
| BL | FG | GND | VCC | 1 V |
| SGD | FG | VCC | VCC | VCC |
| WL0 | GND | Vpass | Vpass | VCC |
| WL1 | GND | Vpass | Vpass | VCC |
| WL2 | GND | Vpass | Vpass | VCC |
| WL3 | GND | Vpass | Vpass | VCC |
| WL4 | GND | VPP | VPP | GND |
| (selected WL) | | | | |
| WL5 | GND | Vpass | Vpass | VCC |
| WL6 | GND | Vpass | Vpass | VCC |
| WL7 | GND | Vpass | Vpass | VCC |
| SGS | FG | GND | GND | VCC |
| VS | FG | GND | GND | GND |
| TP-WELL | VPP | GND | GND | GND |

VPP value is for example from 8 to 20 V and Vpass value is for example from VCC to 12 V. Only eight world lines (in one byte) are shown as the example.

In program operation, byte or page programming and program verification is adopted in the selected cell. High voltage VPP is applied to the selected word line of SONOS cell. The unselected word lines of SONO cells are performed as pass gate transistor (biased to Vpass) to pass BL voltage (GND) to the channel of selected program cell. A high electric filed exits in the O/N/O film of program cell that induces F-N electron tunneling from substrate into SIN storage node. The threshold voltage of program cell increases to positive value that is, for example, defined as “0” state.

In erasing operation, block erase or whole chip erase is performed by applying high voltage VPP on TPW/DNW, and keeping all of the word line voltage of SONOS cells to be ground. Meanwhile, BL, Source, SGD and SGS are set to be floating or VPP that can prevent high electric field from crossing the gate and the S/D junction of selection transistor region. While high electric filed crosses the O/N/O film of SONOS cell, it causes the F-N hole injection from the substrate through the bottom tunnel oxide into SiN storage node, and causes the cell threshold voltage down to negative value that is defined as “1” state.

Alternative way of erase operation is negative gate erasing by applying negative voltage on control gate, and all of the others terminal GND.

Regarding to program disturb, the same WL of program inhibit cell can be alleviated in program disturbance because of unselected BL voltage is held at VCC that simply passes to the channel of the program inhibited cell. In case of this program inhibited cell can prevent word line disturbance. On the other hand, program inhibited cells in the same BL can prevent the program disturbance from occurring because the gate voltage Vpass does not cause electron tunnel through tunnel oxide.

In read operation, BL is applied with a voltage, such as around 1V. The word line of the selected cell is held at GND, the other word lines of un-selected SONOS cells are biased at VCC. Source is set to GND.

The invention particularly propose the depletion mode memory cell in nonvolatile memory device. The operation speed can be improved. Particularly, the erasing speed can be improved.

It will be apparent to those skilled in the art that various modifications and variations can be made to the structure of the present invention without departing from the scope or spirit of the invention. In view of the foregoing, it is intended that the present invention covers modifications and variations of this invention provided they fall within the scope of the following claims and their equivalents.

1. A cell structure of a nonvolatile memory device, comprising:
a substrate, doped with first-type dopants;
a charge-storing structure layer, disposed on the substrate;
a gate electrode, disposed on the charge storing layer;
source/drain (S/D) regions, formed in the substrate at each side of the gate electrode; and
a threshold voltage adjusting region, formed at a surface region of the substrate under the charge-storing structure layer to have a depletion operation mode, wherein the threshold voltage adjusting region is doped with second-type dopants, opposite to the first-type dopants.

2. The cell structure of claim 1, wherein the first-type dopants are P-type dopants and the second-type dopants are N-type dopants.

3. The cell structure of claim 1, wherein the gate electrode is a part of a word line.

4. The cell structure of claim 1, wherein one of the S/D regions is coupled to a bit line, and another one of the S/D regions is coupled to source voltage.

5. The cell structure of claim 1, wherein the charge-storing structure layer comprises a bottom oxide layer on the substrate, a charge trapping layer on the bottom oxide layer, and a top oxide layer on the charge trapping layer.

6. The cell structure of claim 5, wherein the charge trapping layer is a nitride layer.

7. A cell string structure with respect to a bit line, comprising:
a substrate doped with first-type dopants;
a plurality of charge-storing structure layers, formed on the substrate within the memory well;
a plurality of memory gate layers respectively formed on the charge-storing structure layers;
a plurality of threshold voltage adjusting region, formed at a surface region of the substrate under the charge-storing structure layers to have a depletion operation mode, wherein the threshold voltage adjusting region is doped with second-type dopants, opposite to the first-type dopants; and
a plurality of doped regions, formed in the substrate at each side of the memory gate layers, so that a plurality of memory cells are formed and coupled in series.

8. The cell string structure of claim 7, further comprising:
a first selection gate and a first gate dielectric layer, formed on the substrate adjacent to one end of the doped regions;
a bit line doped region, formed in the substrate at one side of the first selection gate for receiving a bit line voltage;
a second selection gate and a second gate dielectric layer, formed on the substrate adjacent to another end of the doped regions;
a source-voltage doped region, formed in the substrate at one side of the second selection gate for receiving a source voltage.

9. The cell string structure of claim 8, wherein the first-type dopants are P-type dopants and the second-type dopants are N-type dopants.

10. The cell string structure of claim 7, wherein each of the memory gate layers is a part of a word line.

11. The cell string structure of claim 7, wherein each of the charge-storing structure layer comprises a bottom oxide layer on the substrate, a charge trapping layer on the bottom oxide layer, and a top oxide layer on the charge trapping layer.

12. The cell string structure of claim 11, wherein the charge trapping layer is a nitride layer.

13. A structure of a nonvolatile memory device, comprising
a substrate, wherein the substrate include a peripheral area and a memory area, wherein a plurality of devices are formed in the peripheral area and a plurality memory cells are formed in the memory area within a doped well being doped with first-type dopants,
wherein each of the memory cells comprises:
a charge-storing structure layer, disposed on the substrate within the doped well;
a gate electrode, disposed on the charge storing layer;
source/drain (S/D) regions, formed in the substrate at each side of the gate electrode; and
a threshold voltage adjusting region, formed at a surface region of the substrate under the charge-storing structure layer to have a depletion operation mode, wherein the threshold voltage adjusting region is doped with second-type dopants, opposite to the first-type dopants.

14. The structure of claim 13, wherein the first-type dopants are P-type dopants and the second-type dopants are N-type dopants.

15. The structure of claim 13, wherein the gate electrode is a part of a word line.

16. The structure of claim 13, wherein one of the S/D regions is coupled to a bit line, and another one of the S/D regions is coupled to source voltage.

17. The structure of claim 13, wherein the charge-storing structure layer comprises a bottom oxide layer on the substrate, a charge trapping layer on the bottom oxide layer, and a top oxide layer on the charge trapping layer.

18. The structure of claim 17, wherein the charge trapping layer is a nitride layer.
